(19) United States
(12) Patent Application Publication
(10) Pub. No.: US 2019/0018514 A1
(43) Pub. Date: Jan. 17, 2019

(54) TOUCH DISPLAY MODULE, MANUFACTURING METHOD THEREOF AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Lingyan WU, Beijing (CN); Yang LIU, Beijing (CN); Lei ZHANG, Beijing (CN); Taofeng XIE, Beijing (CN); Wei ZHANG, Beijing (CN); Guangchao WEI, Beijing (CN)

(21) Appl. No.: 15/743,488

(22) PCT Filed: Jul. 31, 2017
(86) PCT No.: PCT/CN2017/095234

§ 371 Date: Jan. 10, 2018

(30) Foreign Application Priority Data
Aug. 25, 2016 (CN) 201610726278.6

(51) Int. Cl. G06F 3/044; H05K 3/46

(52) U.S. Cl. CPC G06F 3/044; H05K 3/467; H05K 2201/10128; H05K 2201/0326; G06F 2203/04103; H05K 2203/0502

(57) ABSTRACT

A touch display module, a manufacturing method thereof and a display device are provided. The touch display module includes a display panel and a touch module attached to the display panel; the touch module includes a touch region provided with a touch electrode and a border region provided with a black matrix, and the touch module includes a base substrate and includes a first anti-shadow layer and a second anti-shadow layer which are at a side, close to the display panel, of the base substrate; the first anti-shadow layer is between the touch electrode and the base substrate; the second anti-shadow layer is at a side, away from the base substrate, of the touch electrode; and in a dark state display mode, a color difference between the touch region and the border region is smaller than a preset value.

### TECHNICAL FIELD

Embodiments of the present disclosure relate to a touch display module, a manufacturing method thereof and a display device.

### BACKGROUND

For most touch display products, after a touch module and a display panel of each touch display product are bonded together, obvious color difference appears between a touch region and a border region of the touch display product. In order to improve a visual effect, the color difference between the touch region and the border region needs to be reduced as much as possible, to achieve an integral black effect. A solution for OGS (One Glass Solution) touch modules is to change a black matrix material in the border region, but the effect of this solution is not satisfactory.

### SUMMARY

Embodiments of the present disclosure provide a touch display module, a manufacturing method thereof and a display device. The embodiments of the present disclosure reduce a color difference between a touch region and a border region.

At least one embodiment of the present disclosure provides a touch display module, which includes a display panel and a touch module attached to the display panel; the touch module includes a touch region provided with a touch electrode and a border region provided with a black matrix, and the touch module includes a base substrate and includes a first anti-shadow layer and a second anti-shadow layer which are at a side, close to the display panel, of the base substrate; the first anti-shadow layer is between the touch electrode and the base substrate; the second anti-shadow layer is at a side, away from the base substrate, of the touch electrode; and in a dark state display mode, a color difference between the touch region and the border region is smaller than a preset value.

For example, a color difference ΔE between the touch region and the border region in CIELab color model is smaller than 1 in the dark state display mode.

For example, in the dark state display mode, a color difference between the black matrix and a stack structure of the first anti-shadow layer, the touch electrode and the second anti-shadow layer is smaller than the preset value.

For example, the first anti-shadow layer is a layer closest to the base substrate.

For example, the touch electrode includes a first touch electrode and a second touch electrode which is insulated from the first touch electrode and includes a plurality of sub-electrodes; and the touch module further includes: a conductive layer includes a bridge pattern, the bridge pattern in the conductive layer connecting together the sub-electrodes of the second touch electrode; and a first insulation layer which is between the conductive layer and the first touch electrode and exposes two ends of the bridge pattern.

For example, the touch module further includes a flexible printed circuit connection part, which is electrically connected with the touch electrode and is provided in the border region; and the second anti-shadow layer exposes a region provided with the connection part.

For example, the touch module further includes a second insulation layer, and the second insulation layer is between the second anti-shadow layer and each of the touch electrode, the first insulation layer and the black matrix.

For example, a material of the second insulation layer is an optical adhesive.

For example, at least one of the first anti-shadow layer and the second anti-shadow layer is in direct contact with the touch electrode.

For example, the first anti-shadow layer is a composite film includes a niobium pentoxide film and a silicon dioxide film.

For example, the second anti-shadow layer is a composite film includes a niobium pentoxide film and a silicon dioxide film; or the second anti-shadow layer is a silicon oxynitride film.

For example, a material of the touch electrode and a material of the conductive layer are indium tin oxide.

For example, a thickness of the touch electrode is about 900 Å, a thickness of the niobium pentoxide film in the first anti-shadow layer is about 80 Å˜100 Å, a thickness of the silicon dioxide film in the first anti-shadow layer is about 300 Å˜500 Å, a thickness of the niobium pentoxide film in the second anti-shadow layer is about 80 Å˜100 Å, a thickness of the silicon dioxide film in the second anti-shadow layer is about 300 Å˜500 Å, and a thickness of the silicon oxynitride layer in the second anti-shadow layer is in a range of about 500˜900 Å.

For example, the thickness of the niobium pentoxide film in the first anti-shadow layer is about 100 Å, the thickness of the silicon dioxide film in the first anti-shadow layer is about 300 Å, and the thickness of the silicon oxynitride film in the second anti-shadow layer is about 900 Å.

For example, the thickness of the niobium pentoxide film in the first anti-shadow layer is about 100 Å, the thickness of the silicon dioxide film in the first anti-shadow layer is about 300 Å, the thickness of the niobium pentoxide film in the second anti-shadow layer is about 90 Å, and the thickness of the silicon dioxide film in the second anti-shadow layer is about 200 Å.

For example, the touch display module further includes an optical adhesive layer, and the optical adhesive layer connects together the display panel and the second anti-shadow layer.

At least one embodiment of the present disclosure provides a manufacturing method of the touch display module according to any one of the above embodiments, and the method includes: forming the first anti-shadow layer on the base substrate; forming the touch electrode at a side of the base substrate, at which side the first anti-shadow layer is formed; forming the second anti-shadow layer at the side of the base substrate, at which side the touch electrode is formed, to form the touch module; and attaching the side of the base substrate to the display panel, at which side the first anti-shadow layer and the second anti-shadow layer are formed.

For example, the manufacturing method further includes: after forming the touch electrode and before forming the second anti-shadow layer, forming a flexible printed circuit connection part, which is electrically connected with the touch electrode and is provided in the border region. In the method, the forming the second anti-shadow layer includes: shielding a region provided with the connection part by using a mask to form the second anti-shadow layer at the side of the base substrate, at which side the touch electrode is formed; or forming a second anti-shadow film, and removing a portion of the second anti-shadow film covering the region provided with the connection part by using a photoresist, to form the second anti-shadow layer.

At least one embodiment of the present disclosure further provides a touch display module, which includes a display panel and a touch module; the display panel includes an array substrate and an opposite substrate which are opposite to each other, and the opposite substrate is between the array substrate and the touch module; and the touch module includes a touch electrode, a first anti-shadow layer and a second anti-shadow layer, and the touch electrode is between the first anti-shadow layer and the second anti-shadow layer in an arrangement direction of the display panel and the touch module.

For example, the touch module includes a touch region provided with the touch electrode and a border region provided with a black light-blocking material; and in a dark state display mode, a color difference between the black light-blocking material and a stack structure of the first anti-shadow layer, the touch electrode and the second anti-shadow layer is smaller than a preset value.

At least one embodiment of the present disclosure provides a display device includes the touch display module according to any one of the above embodiments.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1A is a schematic structural view of a touch display module provided by embodiments of the present disclosure;

FIG. 1B is a schematic structural view of a touch module in the touch display module provided by the embodiments of the present disclosure;

FIG. 2A is a flow chart of a manufacturing method of the touch display module provided by the embodiments of the present disclosure;

FIG. 2B is a flow chart of partial steps of the manufacturing method of the touch display module provided by the embodiments of the present disclosure;

FIG. 2C is a further flow chart of partial steps of the manufacturing method of the touch display module provided by the embodiments of the present disclosure;

FIGS. 3a-3g are schematic structural views of respective steps in a manufacturing process of the touch module in the touch display module provided by the embodiments of the present disclosure;

FIG. 3f′ is a schematic top view of a partial structure in manufacturing an FPC connection part provided by the embodiments of the present disclosure; and

FIG. 4 is another schematic structural view of the touch display module provided by the embodiments of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. The terms “include,” “including,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

Embodiments of the present disclosure provide a touch display module, a manufacturing method of the touch display module and a display device. The touch display module includes a display panel and a touch module attached to the display panel; the touch module includes a touch region provided with a touch electrode and a border region provided with a black matrix, and the touch module includes a base substrate and includes a first anti-shadow layer and a second anti-shadow layer which are at a side, close to the display panel, of the base substrate; the first anti-shadow layer is between the touch electrode and the base substrate; the second anti-shadow layer is at a side, away from the base substrate, of the touch electrode; and in a dark state display mode, a color difference between the touch region and the border region is smaller than a preset value. For example, the preset value is greater than 0 and smaller than or equal to 1. For example, in the dark state display mode, a color difference between the black matrix and a stack structure of the first anti-shadow layer, the touch electrode and the second anti-shadow layer (namely the combination of the first anti-shadow layer, the touch electrode and the second anti-shadow layer) is smaller than the preset value.

For example, a thickness of the second anti-shadow layer is greater than a thickness of the first anti-shadow layer, so that a better integral black effect is obtained. Alternatively, the thickness of the second anti-shadow layer is equal to or smaller than the thickness of the first anti-shadow layer.

For example, the second anti-shadow layer is configured to make an optical refractive index of a region (the touch region) provided with the touch electrode equal to an optical refractive index of other region (such as the border region). Generally, in a manufacturing process of the touch display module, in a situation that the optical refractive index of the region provided with the touch electrode is close to the optical refractive index of the other region, that is, the error therebetween is within a preset range, it is considered that the optical refractive index of the region provided with the touch electrodes is equal to the optical refractive index of the other region. In this way, a shadow of the touch electrode is eliminated.

For example, the thickness of the second anti-shadow layer is greater than the thickness of the first anti-shadow layer because the second anti-shadow layer further needs to eliminate the shadow of the touch electrode. In the embodiments of the present disclosure, the first anti-shadow layer and the second anti-shadow layer have predetermined thicknesses so that the color difference between the touch region and the border region in the dark display mode is smaller than the preset value, and the preset value is a maximum color difference required for the integral black effect. For example, in the dark state display mode, the color difference ΔE between the touch region and the border region in CIELab color model is smaller than 1, and the CIELab color model is a kind of color model which is determined by the CIE (Commission Internationale Eclairage) organization and theoretically includes all colors visible for human eyes. In the case that the color difference ΔE between the touch region and the border region in the CIELab color model is smaller than 1, the colors of the two regions are the same for viewers. In the CIELab color model, L represents a luminance value, a represents a red-green value, b represents a yellow-blue value, the color difference between two colors ΔE=\sqrt{ΔL²+Δa²+Δb²}, wherein ΔL represents a difference between the luminance values of the two colors, Δa represents a difference between the red-green values of the two colors, Δb represents a difference between the yellow-blue values of the two colors.

In the embodiments of the present disclosure, the first anti-shadow layer and the second anti-shadow layer are disposed at a display side of the display panel in the touch display module, and the second anti-shadow layer not only eliminates the shadow of the touch electrode, but also makes the color difference between the touch region and the border region very small in the dark state display mode in the cooperation of the first anti-shadow layer, which improves the integral black effect. In addition, the second anti-shadow layer also has a function of protecting the touch module so as to reduce the scratching defect rate in a manufacturing process.

Solutions of the present disclosure are described in more detail below with reference to the accompanying drawings and embodiments.

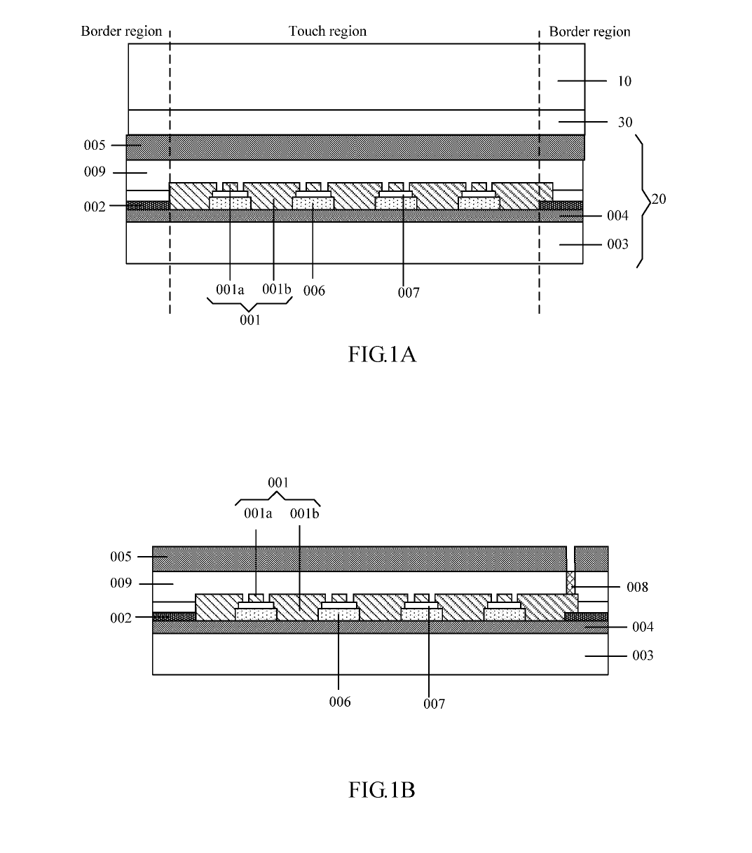

In at least one embodiment of the present disclosure, as illustrated in FIG. 1A, a possible touch display module includes a display panel 10, a touch module 20 and an optical adhesive layer 30 which connects together the display panel 10 and the touch module 20. The structure of the touch module is illustrated in FIG. 1A and FIG. 1B, the touch module 20 includes a touch region provided with a touch electrode 001 and a border region provided with a black matrix 002 (the region provided with the entire black matrix 002 is the border region), the touch module 20 includes a base substrate 003 and the touch module 20 further includes a first anti-shadow layer 004 and a second anti-shadow layer 005 at a side, close to the display panel 10, of the base substrate 003 in both the touch region and the border region; the first anti-shadow layer 004 is between the touch electrode 001 and the base substrate 003, for example, the first anti-shadow layer 004 is in direct contact with the touch electrode 001 and/or the base substrate 003; the second anti-shadow layer 005 is at a side, away from the base substrate 003, of the touch electrode 001, and the black matrix 002 is between the first anti-shadow layer 004 and the second elimination layer 005; and the thickness of the second anti-shadow layer 005 is greater than the thickness of the first anti-shadow layer 004, and the thickness of the first anti-shadow layer 004 and the thickness of the second anti-shadow layer 005 meet the requirement: in a dark state display mode, a color difference ΔE between the touch region and the border region in CIELab color model is smaller than 1.

For example, the first anti-shadow layer 004 is a transparent insulation film covering the entire touch region and the entire border region. For example, both an entire upper surface and an entire lower surface of the first anti-shadow layer 004 are planar.

For example, the second anti-shadow layer 005 is a transparent insulation film that covers at least the entire touch region. For example, both an upper surface and a lower surface of the second anti-shadow layer 005, which are corresponding to the entire touch region, are planar.

The position of the first anti-shadow layer 004 has a certain impact on the integral black effect, and in order to further improve the integral black effect, for example, as shown in FIG. 1A and FIG. 1B, the first anti-shadow layer 004 is a layer closest to the base substrate 003, that is, the first anti-shadow layer 004 is in direct contact with the base substrate 003. For example, the first anti-shadow layer 004 is the layer closest to the base substrate 003, and the second anti-shadow layer 005 is a layer farthest from the base substrate 003. For example, the second anti-shadow layer 005 is in direct contact with the optical adhesive layer 30 (as shown in FIG. 1A), so that a better integral black effect is achieved.

For example, the optical adhesive layer 30 connects together the display panel 10 and the second anti-shadow layer 005, and has a planar structure and covers the entire touch region and the entire border region.

For example, the display panel 10 includes an array substrate and an opposite substrate which are opposite to each other, and a connecting portion which connects together the array substrate and the opposite substrate. For example, the display panel 10 is a liquid crystal panel or an active light-emitting display panel such as an OLED (Organic Light Emitting Diode) display panel.

For example, the touch display module includes a touch electrode disposed along a row direction and a touch electrode disposed along a column direction, one of which serves as a driving electrode and the other one of which serves as a sensing electrode. In a possible embodiment, each of the touch electrode disposed along the row direction and the touch electrode disposed along the column direction is an integrated electrode. In another possible embodiment, one of the touch electrode disposed along the row direction and the touch electrode disposed along the column direction is an integrated electrode, and the other of the touch electrode disposed along the row direction and the touch electrode disposed along the column direction includes a plurality of sub-electrodes. It should be noted that the integrated electrode refers to that the whole electrode is formed by the same layer.

As illustrated in FIG. 1A and FIG. 1B, the touch electrode 001 includes an integrated first touch electrode 001a and a second touch electrode 001b which is insulated from the first touch electrode 001a and includes a plurality of sub-electrodes; and the touch module further includes: a conductive layer 006 including bridge patterns, the bridge patterns in the conductive layer 006 respectively connecting together the sub-electrodes of the second touch electrode 001b; and a first insulation layer 007 which is between the conductive layer 006 and the first touch electrode 001a and exposes two ends of each of the bridge patterns. The first insulation layer 007 mainly functions to insulate the first touch electrode 001a from the second touch electrode 001b. The two ends of each of the bridge patterns in the conductive layer 006 are not covered by the first insulation layer 007 to ensure that the sub-electrodes of the second touch electrode 001b are electrically connected with the two ends of the bridge patterns, respectively. For example, as shown in FIG. 1A and FIG. 1B, the first insulation layer 007 is also located in the region provided with the black matrix 002, and a portion, located in the border region, of the first insulation layer 007 is between the black matrix 002 and the second anti-shadow layer 005, which functions to prevent static electricity.

The touch electrode is connected with a flexible printed circuit (FPC), for example, as illustrated in FIG. 1B, the touch module 20 further includes a flexible printed circuit connection part 008, which is electrically connected with the touch electrode 001 and is provided in the border region; and the second anti-shadow layer 005 exposes a region provided with the FPC connection part 008. In the embodiments, the region provided with the FPC connection part 008 is not shielded by the second anti-shadow layer 005, so as to ensure an electrical connection.

For example, the first anti-shadow layer 004 is a composite film including a niobium pentoxide film and a silicon dioxide film. For example, the niobium pentoxide film is between the silicon dioxide film and the base substrate 003, namely the distance from the niobium pentoxide film to the display panel 10 is greater than the distance from the silicon dioxide film to the display panel 10.

For example, the second anti-shadow layer 005 is a composite film including a niobium pentoxide film and a silicon dioxide film, for example, the distance from the niobium pentoxide film to the display panel 10 is greater than the distance from the silicon dioxide film to the display panel 10; or the second anti-shadow layer 005 is a silicon oxynitride film.

For example, for the above-described materials of the first anti-shadow layer and the second anti-shadow layer, a refractive index of the silicon dioxide film for a light having a wavelength of 550 nm is about 1.4-1.5, for example about 1.47; a refractive index of the niobium pentoxide film for the light having the wavelength of 550 nm is about 2.2-2.5, for example about 2.34; and a refractive index of the silicon oxynitride film for the light having the wavelength of 550 nm is about 1.6-1.7, for example about 1.67.

For example, a material of the touch electrode 001 and a material of the conductive layer 006 are indium tin oxide. In this case, in order to obtain a better integral black effect, a thickness of the touch electrode (namely a thickness of the sub-electrodes of the second touch electrode 001b in a direction perpendicular to a support surface of the base substrate 003) is about 900 Å, a thickness of the niobium pentoxide film in the first anti-shadow layer is about 80 Å˜100 Å, a thickness of the silicon dioxide film in the first anti-shadow layer is about 300 Å˜500 Å, a thickness of the niobium pentoxide film in the second anti-shadow layer is about 80 Å˜100 Å, a thickness of the silicon dioxide film in the second anti-shadow layer is about 300 Å˜500 Å, and a thickness of the silicon oxynitride layer in the second anti-shadow layer is in a range of about 500˜900 Å.

In order to further obtain a better integral black effect, for example, the thickness of the niobium pentoxide film in the first anti-shadow layer is about 100 Å, the thickness of the silicon dioxide film in the first anti-shadow layer is about 300 Å, and a thickness of the silicon oxynitride film in the second anti-shadow layer is about 900 Å.

In order to further obtain a better integral black effect, for example, the thickness of the niobium pentoxide film in the first anti-shadow layer is about 100 Å, the thickness of the silicon dioxide film in the first anti-shadow layer is about 300 Å, the thickness of the niobium pentoxide film in the second anti-shadow layer is about 90 Å, and the thickness of the silicon dioxide film in the second anti-shadow layer is about 200 Å.

What are described above only takes the case that the thickness of the ITO touch electrode is about 900 Å as an example and lists the thicknesses which bring a relatively good integral black effect. In specific implementations, if the ITO touch electrode has other thickness, the thickness of the second anti-shadow layer is determined according to the thickness of the touch electrode, and then the thickness of the first anti-shadow layer is determined so that the thickness of the first anti-shadow layer and the thickness of the second anti-shadow layer satisfy the requirement that the color difference ΔE between the touch region and the border region in the CIELab color model is smaller than 1.

For example, the thickness of the ITO touch electrode is about 450 Å, the thickness of the silicon dioxide film in the first anti-shadow layer is about 300 Å, the thickness of the niobium pentoxide film in the first anti-shadow layer is about 100 Å, and the thickness of the silicon oxynitride film in the second anti-shadow layer is about 700 Å; the thickness of the ITO touch electrode is about 900 Å, the thickness of the silicon dioxide film in the first anti-shadow layer is about 300 Å, the thickness of the niobium pentoxide film in the first anti-shadow layer is about 80 Å, and the thickness of the silicon oxynitride film in the second anti-shadow layer is about 500 Å; and the thickness of the ITO touch electrode is about 1200 Å, the thickness of the silicon dioxide film in the first anti-shadow layer is about 300 Å, the thickness of the niobium pentoxide film in the first anti-shadow layer is about 90 Å, and the thickness of the silicon oxynitride film in the second anti-shadow layer is about 800 Å.

For example, the touch module as illustrated in FIG. 1A and FIG. 1B further includes a second insulation layer 009, the second insulation layer 009 is between the second anti-shadow layer 005 and each of the touch electrode 001, the first insulation layer 007 and the black matrix 002.

For example, the second insulation layer 009 adopts materials except the material having an anti-shadow effect on the touch electrode. For example, the material of the second insulation layer 009 does not include any of niobium pentoxide, silicon dioxide, and silicon oxynitride. For example, the material of the second insulation layer 009 is a transparent optical adhesive, so as to prevent the second insulation layer 009 from increasing the color difference between the black matrix and the stack structure of the first anti-shadow layer, the second anti-shadow layer and the touch electrode.

For example, at least one of the first anti-shadow layer 004 and the second anti-shadow layer 005 is in direct contact with the touch electrode 001. In this way, it is avoided that the color difference between the black matrix and the laminated structure of the first anti-shadow layer, the second anti-shadow layer and the touch electrode is increased caused by an insulation between the anti-shadow layer and the touch electrode.

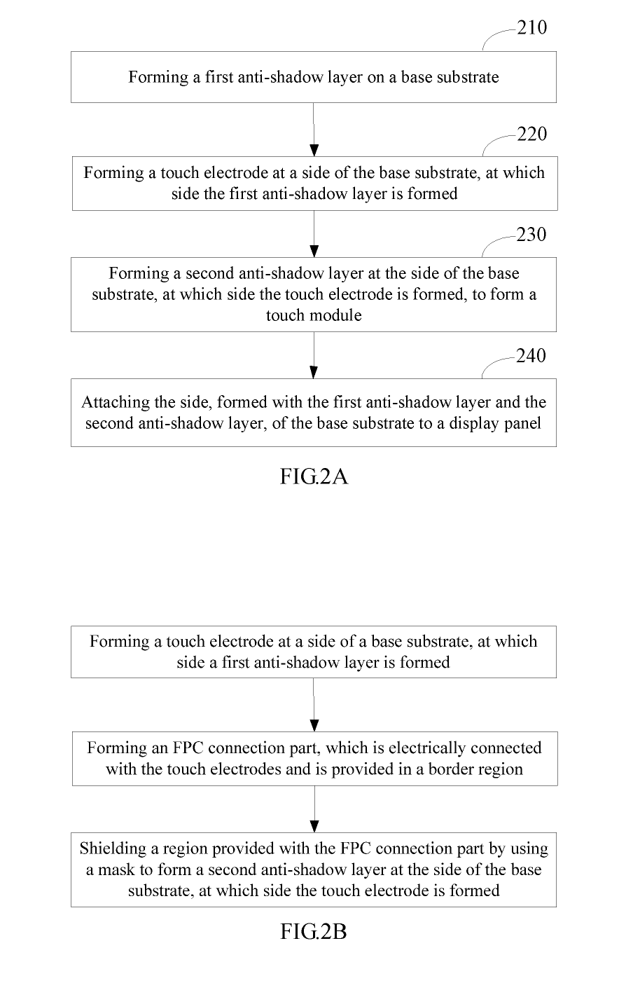

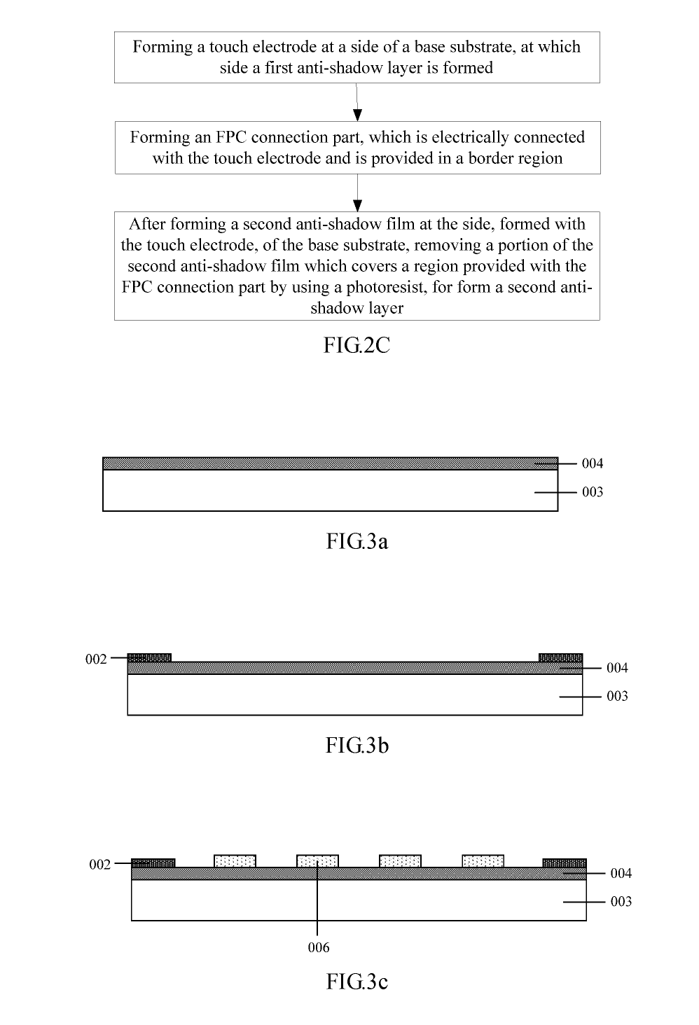

Based on the same inventive concept, the embodiments of the present disclosure further provide a manufacturing method of the touch display module according to any one of the above embodiments. As shown in FIG. 2A, the method includes at least the following steps: step 210, forming the first anti-shadow layer on the base substrate; step 220, forming the touch electrode at a side, formed with the first anti-shadow layer, of the base substrate; step 230, forming the second anti-shadow layer at the side, formed with the touch electrode, of the base substrate to form the touch module; and step 240, attaching the side, formed with the first anti-shadow layer and the second anti-shadow layer, of the base substrate to the display panel. In the method, for example, the thickness of the second anti-shadow layer is greater than the thickness of the first anti-shadow layer, and the thickness of the first anti-shadow layer and the thickness of the second anti-shadow layer satisfy the requirement that in the dark state display mode, the color difference between the touch region and the border region is smaller than the preset value, for example, the preset value is greater than 0 and smaller than or equal to 1.

In the embodiments of the present disclosure, the second anti-shadow layer is configured to make the optical refractive index of the region provided with the touch electrode equal to the optical refractive index of other region. In the manufacturing process of the touch display module, in a situation that the optical refractive index of the region provided with the touch electrode is close to the optical refractive index of the other region, that is, the error therebetween is within a preset range, it is considered that the optical refractive index of the region provided with the touch electrode is equal to the optical refractive index of the other region. In this way, the shadow of the touch electrode is eliminated.

In at least one embodiment, the thickness of the second anti-shadow layer is greater than the thickness of the first anti-shadow layer because the second anti-shadow layer further needs to eliminate the shadow of the touch electrode. In the embodiments of the present disclosure, the first anti-shadow layer and the second anti-shadow layer with predetermined thicknesses make the color difference between the touch region and the border region in the dark display mode smaller than the preset value, and the preset value is the maximum color difference required for the integral black effect. For example, in the case that the color difference ΔE between the touch region and the border region in the CIELab color model is smaller than 1, the colors of the two regions are the same for viewers. In the CIELab color model, L represents the luminance value, a represents the red-green value, b represents the yellow-blue value, the color difference between two colors ΔE=\sqrt{ΔL+Δa²+Δb²}, wherein ΔL represents the difference between the luminance values of the two colors, Δa represents the difference between the red-green values of the two colors, Δb represents the difference between the yellow-blue values of the two colors.

In the embodiments of the present disclosure, the first anti-shadow layer and the second anti-shadow layer are disposed in the touch display module, and the second anti-shadow layer not only eliminates the shadow of the touch electrode, but also makes the color difference between the touch region and the border region very small in the dark state display mode in the cooperation of the first anti-shadow layer, which improves the integral black effect. In addition, the second anti-shadow layer also has the function of protecting the touch module so as to reduce the scratching defect rate in the manufacturing process.

For example, after forming the touch electrode at the side, formed with the first anti-shadow layer, of the base substrate and before forming the second anti-shadow layer at the side, formed with the touch electrode, of the base substrate, as illustrated in FIG. 2B and FIG. 2C, the manufacturing method provided by at least one embodiment of the present disclosure further includes: forming the flexible printed circuit (FPC) connection part, which is electrically connected with the touch electrodes and is provided in the border region. Correspondingly, the forming the second anti-shadow layer at the side, formed with the touch electrode, of the base substrate includes: shielding the region provided with the FPC connection part by using a mask to form the second anti-shadow layer at the side of the base substrate, at which side the touch electrode is formed (as illustrated in FIG. 2B); or forming a second anti-shadow film at the side, formed with the touch electrode, of the base substrate, and removing a portion of the second anti-shadow film covering the region provided with the FPC connection part by using a photoresist, to form the second anti-shadow layer (as illustrated in FIG. 2C).

In the embodiments, the FPC connection part is not covered by the second anti-shadow layer, and thus the second anti-shadow layer does not affect the conductivity of the FPC connection part.

In the following, taking the example that the touch electrode is ITO electrode of about 900 Å, detailed descriptions are given to the manufacturing method of the touch display module according to the embodiments of the present disclosure.

The touch module in at least one embodiment is an OGS touch module, and the specific steps for making the touch module include the following steps 1 to 8.

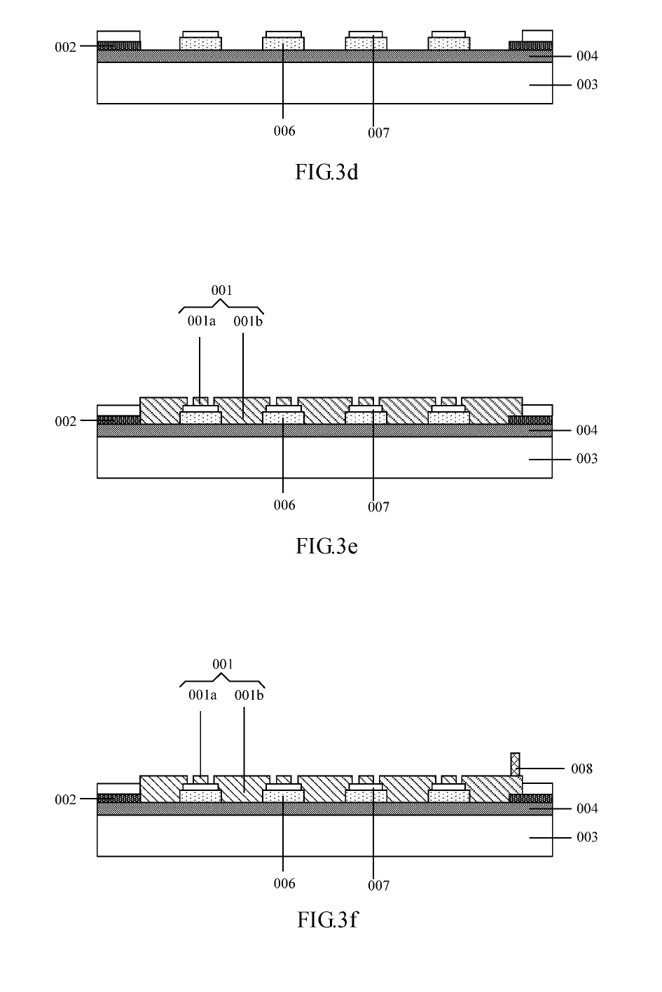

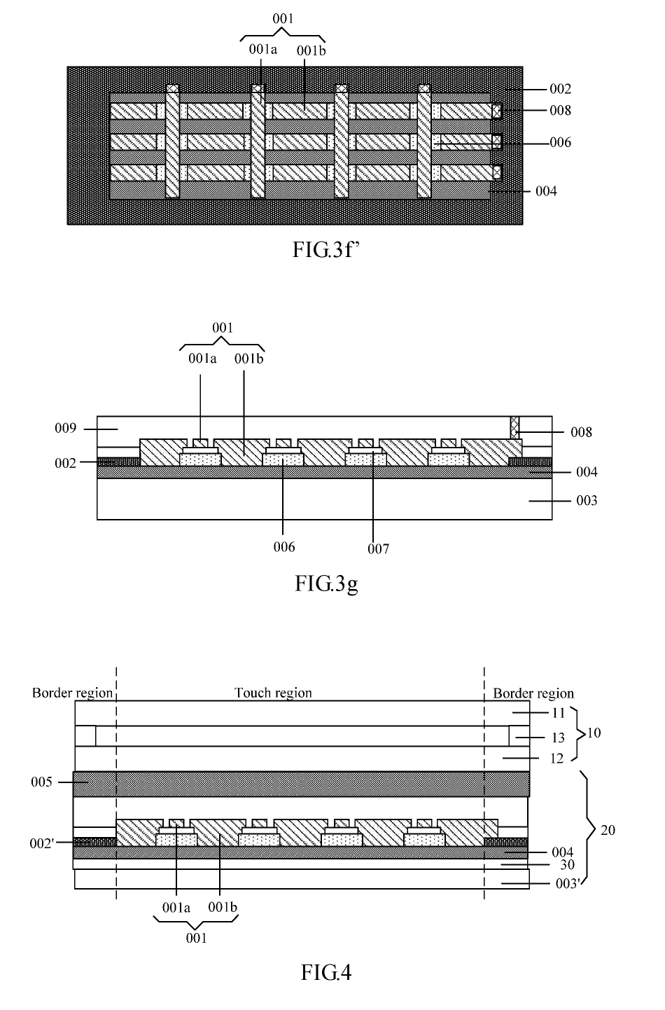

Step 1: as shown in FIG. 3a, the first anti-shadow layer 004 is formed on the base substrate 003.

For example, the base substrate 003 is a glass substrate, a quartz substrate, or a plastic substrate.

For example, the first anti-shadow layer 004 in this step includes the niobium pentoxide film and the silicon dioxide film stacked sequentially, and the thicknesses of the niobium pentoxide film and the silicon dioxide film are about 100 Å and about 300 Å, respectively.

For example, in this step, the first anti-shadow layer is formed by a sputtering process, so that the stability of the first anti-shadow layer is better.

Step 2: as shown in FIG. 3b, the black matrix 002 is formed in the border region at the side of the base substrate 003, at which side the first anti-shadow layer 004 is formed.

In this step, for example, a black matrix film is formed to cover the first anti-shadow layer 004, and then a photolithography process is performed to form the black matrix in the border region.

Step 3: as shown in FIG. 3C, the conductive layer 006 having the bridge patterns is formed on the base substrate 003.

Step 4: as shown in FIG. 3d, the first insulation layer 007 is formed at the side, formed with the conductive layer 006, of the base substrate 003, so that the first insulation layer 007 is located on the black matrix 002 and the conductive layer 006 and exposes the two ends of each bridge pattern of the insulation layer 006.

Step 5: as shown in FIG. 3e, the first touch electrode 001a and the second touch electrode 001b are formed at the side, formed with the first insulation layer 007, of the base substrate 003, and the sub-electrodes of the second touch electrode 001b are electrically connected through the bridge patterns respectively.

Step 6: as shown in FIG. 3f, the FPC connection part 008 which is electrically connected to the first touch electrode 001a and the second touch electrode 001b is formed at the side, formed with the first touch electrode 001a and the second touch electrode 001b, of the base substrate 003, referring to the top view of the partial structure shown in FIG. 3f′.

Step 7: as shown in FIG. 3g, the second insulation layer 009 covering the black matrix 002, the first touch electrode 001a, the second touch electrode 001b and the first insulation layer 007 is formed at the side of the base substrate 003, at which side the FPC connection part 008 is formed.

It can be seen from FIG. 3g that the FPC connection part 008 is not covered by the second insulation layer 009 but is exposed to ensure its conductivity. In addition, for example, partial surfaces of some thick ground (GND) lines are also exposed.

Step 8: a mask is used to shield the region where the FPC connection part 008 is located; alternatively, a film for forming the second anti-shadow layer is formed by sputtering and then is etched by using a photoresist, so as to form the second anti-shadow layer 005 at the side, formed with the second insulation layer 009, of the base substrate 003. The structure obtained in this step can be seen in FIG. 1.

In this step, for example, the second anti-shadow layer is the silicon oxynitride film and has the thickness of about 900 Å; alternatively, the second anti-shadow layer includes the niobium pentoxide film and the silicon dioxide film which are sequentially stacked and have thicknesses of about 90 Å and about 200 Å, respectively.

In this step, for example, the second anti-shadow layer is formed by sputtering, so that the stability of the second anti-shadow layer is better.

After the touch module is fabricated according to the above steps, the side, formed with the first anti-shadow layer and the second anti-shadow layer, of the base substrate 003 is completely adhered to the display panel to fabricate the touch display module. The touch display module obtained by the manufacturing method of the embodiments achieves that the color difference ΔE between the touch region and the border region is smaller than 1 in the CIELab color model in the dark state display mode, thereby greatly improving the integral black effect.

At least one embodiment of the present disclosure further provides a touch display module, and as illustrated in FIG. 4, the touch display module includes a display panel 10 and a touch module 20. The display panel 10 includes an array substrate 11 and an opposite substrate 12 (for example a color filter substrate) which are opposite to each other, and a connecting portion 13 (for example, the connecting portion is made of a sealing material) which connects together the array substrate 11 and the opposite substrate 12; the opposite substrate 12 is between the array substrate 11 and the touch module 20; and the touch module 20 includes a touch electrode 001 (for example, the touch electrode 001 includes a first touch electrode 001a and a second touch electrode 001b which have intersecting extending directions), a first anti-shadow layer 004 and a second anti-shadow layer 005, and the touch electrode 001 is between the first anti-shadow layer 004 and the second anti-shadow layer 005 in an arrangement direction of the display panel 10 and the touch module 20.

In the embodiments of the present disclosure, by forming anti-shadow layers respectively on both sides of the touch electrode 001, the anti-shadow effect is effectively improved.

For example, the touch module includes a touch region provided with the touch electrode 001 and a border region provided with a black light-blocking material (for example, a black matrix) 002′; and in a dark state display mode, a color difference between the black light-blocking material and a stack structure of the first anti-shadow layer 004, the touch electrode 001 and the second anti-shadow layer 005 is smaller than a preset value, for example, the preset value is greater than 0 and smaller than or equal to 1. In this way, the color difference between the touch region and the border region is reduced, so as to improve the integral black effect.

For example, the first anti-shadow layer 004 is located at a side, away from the opposite substrate 12, of the touch electrode 001, the second anti-shadow layer 005 is located between the touch electrode 001 and the opposite substrate 12, and the thickness of the second anti-shadow layer 005 is greater than the thickness of the first anti-shadow layer 004. This can get a better integral black effect.

For example, the touch display module adopts an OGS mode, that is, the touch module 20 is attached to the display panel through an optical adhesive layer as shown in FIG. 1A. Alternatively, the touch display module adopts an on-cell mode, that is, the touch module 20 is directly formed on the opposite substrate 12 of the display panel 10 and is attached to a cover 003′ via an optical adhesive layer 30 (for example, the first anti-shadow layer 004 is in direct contact with the optical adhesive layer 30), as shown in FIG. 4. In these modes, the distance from the second anti-shadow layer 005 to the display panel 10 is smaller than the distance from the first anti-shadow layer 004 to the display panel 10.

The arrangement of each structure shown in FIG. 4 may be referred to the related description in the embodiments shown in FIG. 1, and repeated descriptions are omitted herein.

Based on the same inventive concept, the embodiments of the present disclosure further provide a display device, which includes the touch display module according to any one of the above embodiments.

In the touch display module, the manufacturing method of the touch display module and the display device provided by the embodiments of the present disclosure, the first anti-shadow layer and the second anti-shadow layer are disposed in the touch display module, and the second anti-shadow layer not only eliminates the shadow of the touch electrode, but also makes the color difference between the touch region and the border region very small in the dark state display mode in the cooperation of the first anti-shadow layer, which improves the integral black effect. In addition, the second anti-shadow layer also has the function of protecting the touch module so as to reduce the scratching defect rate in the manufacturing process.

What are described above is related to the illustrative embodiments of the disclosure only and not limitative to the scope of the disclosure; the scopes of the disclosure are defined by the accompanying claims.

This application claims the benefit of Chinese Patent Application No. 201610726278.6, filed on Aug. 25, 2016, which is hereby entirely incorporated by reference as a part of the present application.

1. A touch display module, including:
a display panel; and
a touch module attached to the display panel, wherein the touch module includes a touch region provided with a touch electrode and a border region provided with a black matrix, and the touch module includes a base substrate and includes a first anti-shadow layer and a second anti-shadow layer which are at a side, close to the display panel, of the base substrate,
wherein
the first anti-shadow layer is between the touch electrode and the base substrate,
the second anti-shadow layer is at a side, away from the base substrate, of the touch electrode, and
in a dark state display mode, a color difference between the touch region and the border region is smaller than a preset value.

2. The touch display module according to claim 1, wherein a color difference ΔE between the touch region and the border region in CIELab color model is smaller than 1 in the dark state display mode.

3. The touch display module according to claim 1, wherein in the dark state display mode, a color difference between the black matrix and a stack structure of the first anti-shadow layer, the touch electrode and the second anti-shadow layer is smaller than the preset value.

4. The touch display module according to claim 1, wherein the first anti-shadow layer is a layer closest to the base substrate.

5. The touch display module according to claim 1, wherein the touch electrode includes a first touch electrode and a second touch electrode which is insulated from the first touch electrode and includes a plurality of sub-electrodes; and
the touch module further includes:
a conductive layer including a bridge pattern, wherein the bridge pattern in the conductive layer connects together the sub-electrodes of the second touch electrode, and
a first insulation layer which is between the conductive layer and the first touch electrode and exposes two ends of the bridge pattern.

6. The touch display module according to claim 5, wherein the touch module further includes a second insulation layer, the second insulation layer is between the second anti-shadow layer and each of the touch electrode, the first insulation layer and the black matrix.

7. The touch display module according to claim 6, wherein a material of the second insulation layer is an optical adhesive.

8. The touch display module according to claim 1, wherein at least one of the first anti-shadow layer and the second anti-shadow layer is in direct contact with the touch electrode.

9. The touch display module according to claim 1, wherein the touch module further includes a flexible printed circuit connection part, which is electrically connected with the touch electrode and is provided in the border region; and
the second anti-shadow layer exposes a region provided with the connection part.

10. The touch display module according to claim 1, wherein the first anti-shadow layer is a composite film including a niobium pentoxide film and a silicon dioxide film.

11. The touch display module according to claim 10, wherein the second anti-shadow layer is a composite film including a niobium pentoxide film and a silicon dioxide film; or the second anti-shadow layer is a silicon oxynitride film.

12. The touch display module according to claim 11, wherein a material of the touch electrode and a material of the conductive layer are indium tin oxide.

13. The touch display module according to claim 12, wherein a thickness of the touch electrode is about 900 Å, a thickness of the niobium pentoxide film in the first anti-shadow layer is about 80 Å˜100 Å, a thickness of the silicon dioxide film in the first anti-shadow layer is 300 Å˜500 Å, a thickness of the niobium pentoxide film in the second anti-shadow layer is about 80 Å˜100 Å, a thickness of the silicon dioxide film in the second anti-shadow layer is about 300 Å˜500 Å, and a thickness of the silicon oxynitride layer in the second anti-shadow layer is in a range of about 500˜900 Å.

14. The touch display module according to claim 13, wherein
the thickness of the niobium pentoxide film in the first anti-shadow layer is about 100 Å, the thickness of the silicon dioxide film in the first anti-shadow layer is about 300 Å, and the thickness of the silicon oxynitride film in the second anti-shadow layer is about 900 Å, or
the thickness of the niobium pentoxide film in the first anti-shadow layer is about 100 Å, the thickness of the silicon dioxide film in the first anti-shadow layer is about 300 Å, the thickness of the niobium pentoxide film in the second anti-shadow layer is about 90 Å, and the thickness of the silicon dioxide film in the second anti-shadow layer is about 200 Å.

15. The touch display module according to claim 1, further including an optical adhesive layer, wherein the optical adhesive layer connects together the display panel and the second anti-shadow layer.

16. A manufacturing method of the touch display module according to claim 1, including:
forming the first anti-shadow layer on the base substrate;
forming the touch electrode at a side of the base substrate, at which side the first anti-shadow layer is formed;
forming the second anti-shadow layer at the side of the base substrate, at which side the touch electrode is formed, to form the touch module; and
attaching the side of the base substrate to the display panel, at which side the first anti-shadow layer and the second anti-shadow layer are formed.

17. The manufacturing method according to claim 16, further including:
after forming the touch electrode and before forming the second anti-shadow layer, forming a flexible printed circuit connection part, which is electrically connected with the touch electrode and is provided in the border region,
wherein the forming the second anti-shadow layer includes:
shielding a region provided with the connection part by using a mask to form the second anti-shadow layer at the side of the base substrate, at which side the touch electrode is formed; or
forming a second anti-shadow film, and removing a portion of the second anti-shadow film covering the region provided with the connection part by using a photoresist, to form the second anti-shadow layer.

18. A touch display module, including:
a display panel including an array substrate and an opposite substrate which are opposite to each other; and
a touch module, wherein the opposite substrate is between the array substrate and the touch module,
wherein the touch module includes a touch electrode, a first anti-shadow layer and a second anti-shadow layer, and the touch electrode is between the first anti-shadow layer and the second anti-shadow layer in an arrangement direction of the display panel and the touch module.

19. The touch display module according to claim 18, wherein the touch module includes a touch region provided with the touch electrode and a border region provided with a black light-blocking material; and in a dark state display mode, a color difference between the black light-blocking material and a stack structure of the first anti-shadow layer, the touch electrode and the second anti-shadow layer is smaller than a preset value.

20. A display device including the touch display module according to claim 1.
